(19) United States
(12) Patent Application Publication
(10) Pub. No.: US 2019/0214557 A1
(43) Pub. Date: Jul. 11, 2019

(54) ORGANIC MEMRISTOR

(71) Applicant: Xergy Inc., Harrington, DE (US)

(72) Inventor: Bamdad Bahar, Georgetown, DE (US)

(21) Appl. No.: 16/246,143

(22) Filed: Jan. 11, 2019

Related U.S. Application Data
(60) Provisional application No. 62/616,395, filed on Jan. 11, 2018.

(51) Int. Cl. H01L 45/00; H01L 27/24

(52) U.S. Cl. CPC H01L 45/1246; H01L 45/08; H01L 27/2463; H01L 45/146; H01L 45/1641; H01L 45/10

(57) ABSTRACT

An electrochemical neuromorphic organic device (ENODe) memristor has improved performance and lower power requirements through the use of highly conductive polymers, including ionomer, such as sulfonated tetrafluoroethylene based fluoropolymer-copolymer. These ionomers may be more conductive and may have a low equivalent weight. The ionomer may be reinforced with a support material, such as a thin porous polymer. The thickness of the layer may be reduced to no more than about 50 microns and in some cases no more than 5 microns. Other ionomer polymers include highly functionalized styrene-butadiene copolymers and biphynl based ionomers.

### CROSS REFERENCE TO RELATED APPLICATIONS

This application claims the benefit of priority to U.S. provisional patent application No. 62/616,395, filed on Jan. 11, 2018; the entirety of which is hereby incorporated by reference.

### BACKGROUND OF THE INVENTION

### Field of the Invention

This application is directed organic memristors and methods of use.

### Background

### Large Energy Footprint of Digital Economy

As our lives migrate to the digital cloud and as more and more wireless devices of all sorts become part of our lives, electrons follow. And that shift underscores how challenging it will be to reduce electricity use and carbon emissions even as we appear to adopt ‘smart’ technologies.

The digital cloud system derives its value from the fact that it's on all the time. From computer trading floors or massive data centers to your own cell Phones, there is no break time, no off period. That means a constant demand for electricity. As the cloud grows bigger and bigger, and we put more and more of our devices on wireless networks, we'll need more and more electricity. Over 500 TWH of electricity was consumed by data centers alone globally. In the U.S. it is estimated that at least 10% of U.S. electricity capacity can be accounted for directly by computing, and this is the fastest growing electricity consuming sector. We are adding cloud computing capacity at a faster rate than renewable energy generation. Cloud computing capacity has a predicted compound growth rate of 19% over the next decade whereas the capacity increase for renewable energy is slated to increase from 4% to 9% of U.S. generation capacity over next 15 years.

Illustrative examples are as follows: It takes more electricity to stream a high-definition movie over a wireless network than it would have taken to manufacture and ship a DVD of that same movie. According to a recent study by A. T. Kearney, for the mobile industry association GSMA, an average cell phone consumes more electricity than an EPA Energy Star rated refrigerator (361 kWh per year versus 322 kWh annually). We are however, at the early stage of this transition, users of the wireless cloud will be grow to literally billions of users globally

### Reducing Energy Demand for Computing

The human brain is capable of massively parallel information processing while consuming only ˜1-100 fJ per synaptic event. Neuromorphic or cognitive computing as processed in the human brain typically consumes ≈10-20 Watts for selected “human-like” tasks, which can be currently mimicked by a supercomputer with power consumption of several tens of megawatts. It is orders of magnitude more efficient. Therefore, hardware implementation of such brain functionality must be eventually sought for power-efficient computation. In the past decade or so, new devices based on bio-mimicry have been introduced that have the potential to process information with significantly less power consumption (like the human brain).

Inspired by the efficiency of the brain, CMOS-based neural architectures and memristors are being developed for pattern recognition and machine learning. However, the volatility, design complexity and high supply voltages for CMOS architectures, and the stochastic and energy-costly switching of memristors complicate the path to achieve the interconnectivity, information density, and energy efficiency of the brain using either approach.

### Memristors

Memristors however, remain as the leading candidate technology for fulfilling this need are now considered essential elements in information technology. Memristors offer the potential for much higher speed information processing at much lower power utilization.

Memristors can store information as a change in electrical resistance in either digital or analogue form. Also, Redox-based resistive switching memories (ReRAMs) are nanoionics systems that fall within the broader definition of memristors. Their efficiency and simplicity enable a variety of applications beyond non-volatile memories, such as complex neuromorphic architectures and non-von Neumann computing. Memristor crossbars offer reconfigurable non-volatile resistance states and could remove the speed and energy efficiency bottleneck in vector-matrix multiplication, a core computing task in signal and image processing. Using such systems to multiply an analogue-voltage-amplitude-vector by an analogue-conductance-matrix at a reasonably large scale has, however, proved challenging due to difficulties in device engineering and array integration. With the large memristor crossbars, signal processing, image compression and convolutional filtering, are expected to be important applications in the development of leading edge computing.

Problems with Current Technology

Memristor technology is immature. HP a leader in this field, has published literature for HP's devices claim it is comprised of a metal oxide material that relies on the migration of oxygen vacancies to alter the resistance of the device. This oxygen vacancy migration is related to the volume of the device active layer and is thus considered a ‘bulk’ migration, not necessarily a filament through the device. Theoretical designs for multi-layer memristors have a storage capacity of 1 petabyte per cubic centimeter.

Memristors based on metal oxide materials have been described as erratic, with high switching voltages, high forming voltages, and non-repeatability from device-to-device. There are numerous patents (by companies researching metal-oxide resistive RAM) that support the development of a device structure using oxygen vacancies that form a filamentary conduction path or percolation path (e.g., U.S. Pat. Nos. 8,648,418, 9,012,881B2, US20130341584A1). Other types of metal-oxide devices are described in the patent literature to address the erratic switching issues, and the high forming voltages (U.S. Pat. No. 8,062,918B2, US20140054531A1, U.S. Pat. No. 8,441,838). Even more patents address molecular control of the oxygen vacancies through material design and device structure (e.g., U.S. Pat. No. 8,420,478B2). Clearly given this activity, there must be issues with metal oxides as a basis for these devices.

Separately, some of the metal-oxide devices, such as HfOx, appear to be very difficult to design a stable device with. First, it is very difficult to control the concentration of oxygen within a film. Fabrication techniques become complicated every step of the way. Keeping oxygen out of the device after fabrication is also challenging. Bottom-line, it is difficult to fabricate devices with metal-oxides since it is difficult to control or regulate the concentration of oxygen in the device. This means that every time one tries to fabricate devices, they may get different results due to any small change in the way the wafers were processed. Interestingly, HP is rumored to be shutting down their program despite massive advances in processing speeds and power utilization with prototype units.

Also, separately, Intel and Micron established a joint venture to develop and manufacture memory devices, based on patents originally filed by Stanford Ovshinsky, founder of Energy Conversion Devices. In their technology they are using a chalcogenide alloy of germanium, antimony and tellurium (GeSbTe, GST) to form memristors that change phase from crystalline to amorphous structure with electron migration. They can stack these units in 3 dimensions and create crosshatch architectures systems with high density. Intel and Micron will be scaling up production on these units this year. However, these units are designed to work as improved memory devices, but NOT for computation.

Two-terminal memristors based on filament-forming metal oxides or phase change memory materials have recently been demonstrated to function as non-volatile memory that can emulate neuronal and synaptic functions such as long-term potentiation, short-term potentiation, and spike timing dependent plasticity. Crossbar architectures based on these devices have been projected to reduce energy costs for neural algorithms by six orders of magnitude, and recently performed image recognition and data classification when utilized as highly parallel neuromorphic processing units. However, despite recent progress in the fabrication of device arrays, to date no architecture has been shown to operate with the projected energy efficiency while maintaining high accuracy. A major impediment still exists at the device level; specifically, a resistive memory device has not yet been demonstrated with adequate electrical characteristics to fully realize the efficiency and performance gains of a neural architecture. State-of-the-art memristors suffer from excessive write noise, write nonlinearities and high write voltages and currents. Reducing the noise and lowering the switching voltage significantly below 0.3 V (˜10 kT) in a two-terminal device without compromising long-term data retention has proven difficult.

These limitations reduce the accuracy and scalability of current metal oxide and phase change memristors and pose challenges for these devices to approach the energy efficiency of the brain. The inherent advantages of memristors in developing more advanced, higher speed, lower power capability for computation have not been realized. There is clearly, still, a significant opportunity to engage memristors for computation.

### SUMMARY OF THE INVENTION

A critical decision in the design of resistive memory cells is the selection of the ion-transporting solid. Recognizing that different switching mechanisms may be beneficial, organic materials and even bio-inspired materials have been proposed. These materials bring with them the promise of cheap production, flexibility, biocompatibility and the general ease of property modification through the judicious use of organic chemistry. However, early prototype devices have struggled with high variability, long switching times, low endurance and poor retention.

Recently, cells based on poly(3,4-ethylenedioxythiophene):polystyrene sulfonate (PEDOT:PSS) with PFSA (NAFION electrolyte) have shown more promising performance for neuromorphic operations. Using these building blocks, an electrochemical neuromorphic organic device (ENODe) operating with a fundamentally different mechanism from existing memristors has been developed.

These plastic Memristors and related devices render themselves to low-cost manufacturing and flexibility inherent to soft materials. Also, these organic devices benefit from low-power consumption, added functionality, and biocompatibility.

The operation of ENODe is based on the non-volatile control of the conductivity of an organic mixed ionic/electronic conductor. The ENODe is essentially like a concentration battery. During the ‘read’ operation, the cell is disconnected, and the electronic charge of the electrodes remains unaltered by an ion conducting/electron blocking electrolyte. The charge in the electrodes is manipulated during the ‘write’ operation. Hence, ENODe is a type of non-volatile redox cell (NVRC) in which the state of charge determines the electronic conductivity. The main advantage of NVRCs is that the barrier for state retention is decoupled from the barrier for changing states, allowing for the extremely low switching voltages while maintaining non-volatility.

### ENODe Organic Memristors

Prototype memristor devices based on a poly(3,4-ethylenedioxythiophene):polystyrene sulfonate (PEDOT:PSS) film partially reduced with poly(ethylenimine) (PEI) have been developed and tested. The ENODe switch demonstrated low voltage and energy (<10 pJ for 103 μm devices), and displayed >500 distinct, non-volatile conductance states within a ˜1 V range, and achieved high classification accuracy when implemented in neural network simulations.

These Plastic ENODes were fabricated on flexible substrates enabling the integration of neuromorphic functionality in stretchable electronic systems. This Mechanical flexibility makes ENODes compatible with three-dimensional architectures, opening a path towards extreme interconnectivity comparable to the human brain.

The prototype ENODe used a three-terminal device architecture comprising the postsynaptic electrode, a PEI/PEDOT:PSS film, interfaced with a PEDOT:PSS presynaptic electrode via an electrolyte. Upon applying a positive presynaptic potential Vpre to the PEDOT:PSS electrode, cations flow from the presynaptic electrode into the postsynaptic electrode through the electrolyte, resulting in protonation of the PEI, while electrons flow through the external circuit. This causes holes to be removed from the PEDOT backbone in the postsynaptic electrode, thereby reducing its electronic conductivity while ensuring electroneutrality in the electrode. The reaction is reversed upon applying a negative Vpre. While enabling current continuity by ion transport, the electrolyte also acts as a barrier for electronic charge transport, maintaining the electrode conductance state after the presynaptic potential is applied. PEI stabilizes the neutral form of the PEDOT in the PEDOT:PSS/PEI electrode, ensuring that the oxidation state of the postsynaptic electrode is retained. The conductance states are monitored using a postsynaptic potential Vpost. As such, the conductance of the PEDOT:PSS/PEI channel represents the synaptic weight of the connection between two neurons, an essential property of an artificial synapse.

These ENODes exhibit some of the synaptic functions that are the building blocks of neuromorphic computing. To demonstrate the extremely high density of non-volatile states available for computation, a series of 500 pulses were applied, resulting in 500 distinct conductance states. In addition to driving it with Vpre, ENODe can be operated by injecting a presynaptic current pulse exhibiting a nearly perfect linear behavior. ENODes were cycled between two distinct states over 300 times using 10 mV potentiation and depotentiation pulses, demonstrating extremely low noise (<1%), which enables the definition of many states in a small voltage range.

The postsynaptic state is programmed by varying the amplitude or the duration of the presynaptic pulse. The conductance change, is a linear function of presynaptic pulse amplitude and duration, down to approximately millisecond timescales.

As sub-threshold potentiation in neurons is associated with short term plasticity (STP) and paired pulse facilitation (PPF), this functionality was also established in ENODes. Interestingly, the PPF demonstrated exhibits two characteristic timescales, τ1=14 ms and τ2=240 ms, approximately equal to those measured in biological synapses. Additional bio-inspired functionality such as spike timing dependent plasticity (STDP) can be achieved using overlapping pulse design. Although STP is capacitive in nature, applying many short pulses results in long-term potentiation (LTP), a behavior emulating short-term to long-term potentiation found in nature.

Thus, such an organic electronic device made with inexpensive and commercially available plastic materials that behaves like an artificial synapse. This artificial synapse exhibits many non-volatile and reproducible states (>500) and operates at very low voltages. We determined experimentally that our artificial synapse switches with low energy density and we project that just ˜35 aJ is sufficient to switch a sub-micron device, a number smaller than that of biological synapses. Circuit simulations show that networks based on these synapses perform near the theoretical limit.

These all-plastic devices demonstrated the potential for low-cost fabrication of flexible ENODe arrays. Furthermore, bending and folding of arrays may enable three-dimensional densely connected neuromorphic devices. Interestingly, beyond dramatically impacting computing speed and power utilization, the polymeric nature of the synapse opens a range of novel applications and biological integration, flexibility and low cost provide unique opportunities for the adoption of these devices. They could also act as biometric sensors and direct interfaces with the brain opening the tantalizing opportunity to build advanced neural prostheses comprising integrated brain-machine interfaces that combine neural sensing with training.

### More Advanced ENODe Memristor

In recent publications, further enhanced prototype ENODe memristor were constructed utilizing off the shelf 7 mil (175 micron) NAFION (PFSA) electrolyte, and PEDOT:PSS samples ordered from Sigma-Aldrich. Clearly the published devices have not been optimized.

Thinness: In an exemplary embodiment, an ENODe memristor employs an ionomer layer that is thinner, (optionally reinforced, and therefore stronger) and higher functionality (i.e. higher ion exchange capacity). An exemplary ionomer layer may be much thinner than 175 microns in thickness, such as less than 2 mil or 50 microns and preferably under 1 mil or 25 microns, and may ideally be on the order of 10 microns or less, such as only about 2 microns thick or up to about 5 microns thick. Clearly, reducing the thickness of each layer by an order of magnitude will have dramatic impact on the overall performance of the memristors. Reducing the channel thickness reduces the diffusion distance and improves the time response. In an exemplary embodiment, a low equivalent weight ionomer is utilized, having higher ionic conductivity, such as no more than 1000 equivalent weight, no more than 900 equivalent weight, or no more than about 800 equivalent weight. These lower equivalent weight ionomers may be reinforced to maintain structure of the layer. The ionomer may be reinforced with an expanded membrane, or porous polymeric material and the reinforcement material may have a small pore size to retain the ionomer, such as no more than bout 2 microns, no more than 1 micron, may be sub-micron, wherein the average pore size in no more than 1 micron and may have an average pore size of about 0.5 micron or less. Average pore size of materials may be measured using a Porometer from Porous Material Inc, Ithaca, N.Y.

Size and geometry not only dictate operating speed, but also define switching energy. To highlight the path towards ultra-low energy switching of ENODe, power dissipation was measured in devices with areas spanning five orders of magnitude. The power dissipated is determined by P=I×V, and the energy is calculated by integration over the pulse width. The switching energy of our smallest device was measured to be ˜10 pJ, which is comparable to state-of-the-art PCMs that are over three orders of magnitude smaller. Since current scales with area whereas the voltage, determined by the electrochemical overpotential at the polymer/electrolyte interface, remains approximately constant, the switching energy is proportional to the electrode area, with a slope of 390±10 pJ mm-2. Thus, making very small, thin assemblies, we can project an energy cost of 35 aJ for switching a 0.3×0.3 μm device. Therefore, downscaling of ENODe is proposed, and new electrode formulations need to be developed.

In published prototype units different PEDOT:PSS formulations were used to fabricate devices with conductance ranging over three orders of magnitude. The energy advantage of ENODe is further enhanced by the low switching voltage (˜0.5 mV), which greatly reduces the interconnect capacitive loss in arrays and is ˜×103 lower than the ‘write’ voltage for a typical memristor. But clearly more work needs to be done to optimize this assembly.

PEDOT materials purchased off the shelf, generally have low molecular weight and are somewhat brittle.

Improved Polythiophene electrodes: In an exemplary embodiment, an ENODe memristor employs an alternate Polythiophene oligomers, with high electrical conductivity, but greater flexibility and molecular weight, which obviously would render the electrodes to greater process-ability. These oligomers include HOMO and LUMO version, parallel formed Thiophenes, and Thiophenes with higher repetition functional groups I.e. one every 6 groups or less versus off the shelf polymers with functional groups every 10 or more.

Improved Electrolytes: In an exemplary embodiment, an ENODe memristor employs electrolytes with much higher ionic conductivity than NAFION (PFSA), which can also be manufactured readily, from solution forms are claimed. One example is highly functionalized styrene-butadiene copolymers, another possibility is Biphynl based ionomers. In addition, functional moiety could be modified with different groups beyond sulfonic acid. In an exemplary embodiment, a low equivalent weight ionomer is utilized, having higher ionic conductivity, such as no more than 1000 equivalent weight, no more than 900 equivalent weight, or no more than about 800 equivalent weight. These lower equivalent weight ionomers may be reinforced to maintain structure of the layer. The ionomer may be reinforced with an expanded membrane, or porous polymeric material and the reinforcement material may have a small pore size to retain the ionomer, such as no more than bout 2 microns, no more than 1 micron, may be sub-micron, wherein the average pore size in no more than 1 micron and may have an average pore size of about 0.5 micron or less. Average pore size of materials may be measured using a Porometer from Porous Material Inc, Ithaca, N.Y.

Reinforcements: These improvements result in higher performance memristor devices, enabling high volume (low cost) manufacturability. Inventors claim use of reinforcements in each layer to aid manufacturability.

An electrochemical neuromorphic organic device (ENODe) as described herein, or the components comprising an ionomer separating electrodes, may be configured as a capacitor or inductor. A thin ionomer layer may separate electrodes and the composition may be planar, wherein it is utilized as a capacitor or inductor. Any of the ionomers described herein may be utilized in the capacitor or inductor and the ionomer may be reinforced as described herein to enable very thin layers that are durable and mechanically stable.

The summary of the invention is provided as a general introduction to some of the embodiments of the invention, and is not intended to be limiting. Additional example embodiments including variations and alternative configurations of the invention are provided herein.

### BRIEF DESCRIPTION OF SEVERAL VIEWS OF THE DRAWINGS

The accompanying drawings are included to provide a further understanding of the invention and are incorporated in and constitute a part of this specification, illustrate embodiments of the invention, and together with the description serve to explain the principles of the invention.

FIG. 1 shows a cross sectional view of an exemplary organic memristors.

FIG. 2 shows a cross sectional view of an exemplary organic memristors.

FIG. 3 is a scanning electron micrograph of the surface of expanded polytetrafluoroethylene.

Corresponding reference characters indicate corresponding parts throughout the several views of the figures. The figures represent an illustration of some of the embodiments of the present invention and are not to be construed as limiting the scope of the invention in any manner. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

### DETAILED DESCRIPTION OF THE ILLUSTRATED EMBODIMENTS

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Certain exemplary embodiments of the present invention are described herein and are illustrated in the accompanying figures. The embodiments described are only for purposes of illustrating the present invention and should not be interpreted as limiting the scope of the invention. Other embodiments of the invention, and certain modifications, combinations and improvements of the described embodiments, will occur to those skilled in the art and all such alternate embodiments, combinations, modifications, improvements are within the scope of the present invention.

### Definitions

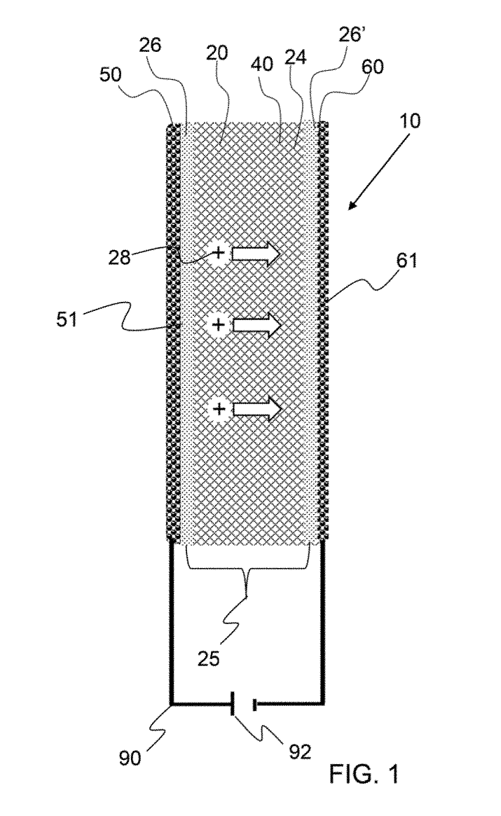

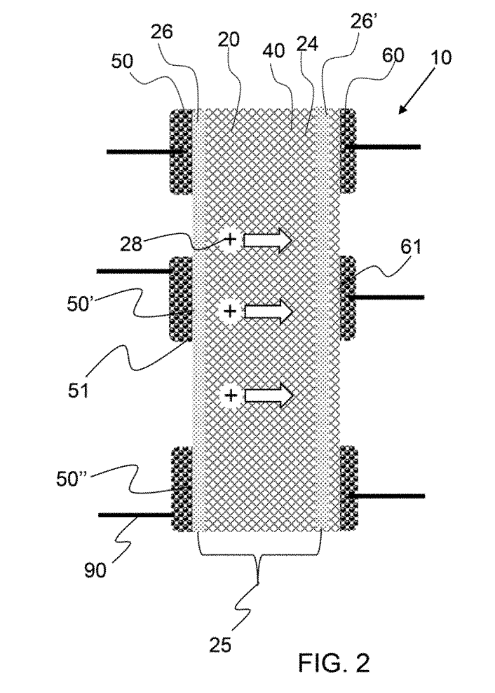

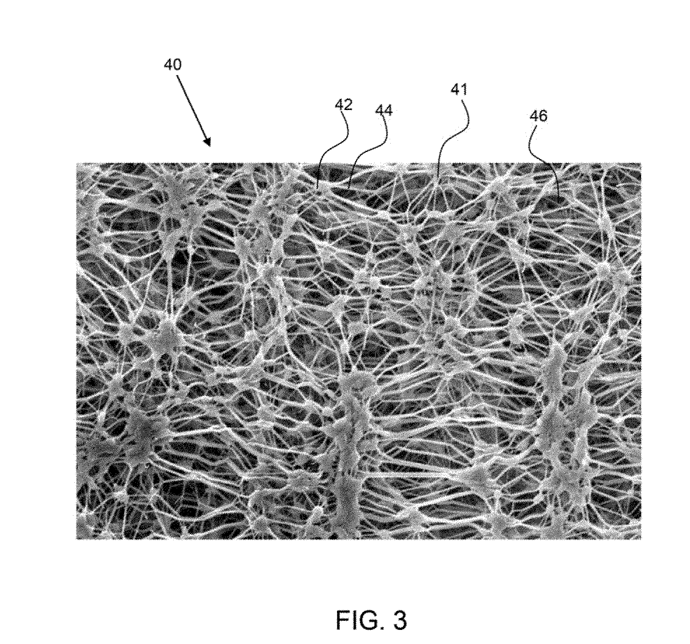

Referring now to FIGS. 1 and 2, an exemplary organic memristor 10 comprises an ionomer layer 20, comprising an ionomer 24 imbibed into the pores of a porous reinforcement layer 40, such as a porous fluoropolymer, including but not limited to expanded polytetrafluoroethylene, as shown in FIG. 3. A layer of ionomer without 26, 26′ may extend along the surface of the ionomer layer 20 without the reinforcement layer, referred to as a butter-coat layer. Note that a composite ionomer lay 21 may have substantially no butter-coat layer, such as less than 0.5 micron thick, or may have a very thin butter-coat layer, such as less than 5 microns, or less than 2 microns. An anode electrode 50 is on an anode side 51 and a cathode electrode 60 is on the cathode side of the organic memristor. An electrical circuit 90 is coupled across the anode and cathode and a power source 92 is coupled with the electrical circuit to provide a voltage to the anode or cathode. The thickness of the organic memristor 25 may be less than 100 microns, such as about 50 microns or less, 25 microns or less, 10 microns or less and even 5 microns or less. There are benefits to the ionomer layer being thin, faster response times as it takes less time for protons 28 to move across the ionomer layer. As shown in FIG. 2, a plurality of discrete electrodes may be configured on the anode or cathode side. The discrete electrodes may be dots of plated electrode material that are not connected to each other.

As shown in FIG. 3, an exemplary reinforcement layer 40 is an expanded polytetrafluoroethylene 41, having nodes 42 interconnected by fibrils 44 and a plurality of pores 46. The pores of the ePTFE may be substantially filled with ionomer to produce an ionomer layer. Note that

It will be apparent to those skilled in the art that various modifications, combinations and variations can be made in the present invention without departing from the scope of the invention. Specific embodiments, features and elements described herein may be modified, and/or combined in any suitable manner. Thus, it is intended that the present invention cover the modifications, combinations and variations of this invention provided they come within the scope of the appended claims and their equivalents.

What is claimed is:

1. An electrochemical neuromorphic organic device (ENODe) memristor comprising:
a) an ionomer layer comprising an ionomer and having a thickness of no more than 100 microns thick;
b) electrodes configured on either side of the ionomer layer.

2. The electrochemical neuromorphic organic device (ENODe) memristor of claim 1, wherein the ionomer layer comprises a reinforcement layer that is porous and has a plurality of pores.

3. The electrochemical neuromorphic organic device (ENODe) memristor of claim 2, wherein the ionomer is configured in the plurality of pores of the reinforcement layer.

4. The electrochemical neuromorphic organic device (ENODe) memristor of claim 3, wherein the reinforcement layer comprises a porous polymer.

5. The electrochemical neuromorphic organic device (ENODe) memristor of claim 4, wherein the reinforcement layer comprises a porous fluoropolymer.

6. The electrochemical neuromorphic organic device (ENODe) memristor of claim 5, wherein the reinforcement layer comprises an expanded polytetrafluoroethylene.

7. The electrochemical neuromorphic organic device (ENODe) memristor of claim 1, wherein the thickness is no more than 50 microns.

8. The electrochemical neuromorphic organic device (ENODe) memristor of claim 1, wherein the thickness is no more than 25 microns.

9. The electrochemical neuromorphic organic device (ENODe) memristor of claim 1, wherein the thickness is no more than 10 microns.

10. The electrochemical neuromorphic organic device (ENODe) memristor of claim 1, wherein the thickness is no more than 5 microns.

11. The electrochemical neuromorphic organic device (ENODe) memristor of claim 1, wherein the ionomer has an equivalent weight of no more than 1000.

12. The electrochemical neuromorphic organic device (ENODe) memristor of claim 1, wherein the ionomer has an equivalent weight of no more than 800.

13. The electrochemical neuromorphic organic device (ENODe) memristor of claim 1, wherein the ionomer comprises sulfonated tetrafluoroethylene based fluoropolymer-copolymer (NAFION).

14. The electrochemical neuromorphic organic device (ENODe) memristor of claim 1, wherein the ionomer comprises perfluorosulfonic acid polymer.

15. The electrochemical neuromorphic organic device (ENODe) memristor of claim 1, wherein the ionomer comprises highly functionalized styrene-butadiene copolymers.

16. The electrochemical neuromorphic organic device (ENODe) memristor of claim 1, wherein the ionomer comprises Biphynl based ionomers.

17. The electrochemical neuromorphic organic device (ENODe) memristor of claim 1, wherein the electrode comprises a polythiophene oligomer.

18. The electrochemical neuromorphic organic device (ENODe) memristor of claim 1, wherein the electrode comprises styrene-butadiene copolymers.

19. The electrochemical neuromorphic organic device (ENODe) memristor of claim 1, wherein the electrode comprises Biphynl based ionomers.

20. The electrochemical neuromorphic organic device (ENODe) memristor of claim 1, wherein the electrode comprises a functional moiety.

21. The electrochemical neuromorphic organic device (ENODe) memristor of claim 20, wherein the functional moiety is modified with sulfonic acid.
